(19) United States
(12) Patent Application Publication
(10) Pub. No.: US 2019/0011477 A1
(43) Pub. Date: Jan. 10, 2019

(54) Convective inertial accelerometer with metamaterial thermal structure

(71) Applicant: William N. Carr, cary, NC (US)

(72) Inventor: William N. Carr, cary, NC (US)

(21) Appl. No.: 15/992,134

(22) Filed: May 29, 2018

Related U.S. Application Data
(63) Continuation-in-part of application No. 15/632,462, filed on Jun. 26, 2017.
(60) Provisional application No. 62/707,208, filed on Oct. 25, 2017.

(51) Int. Cl. G01P 15/00; G01P 15/18; G01P 21/00; G01C 9/02; H01L 29/06

(52) U.S. Cl. CPC G01P 15/008; G01P 15/18; B82Y 15/00; G01C 9/02; H01L 29/0669; G01P 21/00

(57) ABSTRACT

An accelerometer based on convective thermal transport through a fluid is structured without a solid proof mass. Thermal transport through the fluid is sourced and sensed by thermal elements. The thermal elements are comprised of phononic structures which increase power efficiency for accelerometer operation and provide an increased sensitivity to acceleration vectors. The temperature of the sensing element is a function of the vectored acceleration of the enclosed cavity structure. The accelerometer in embodiments provides an extended range for multi-axis accelerations from excitations such as vibration, shock and gravity. Integration of the accelerometer with CMOS signal conditioning circuitry on the same die is convenient.

### STATEMENT OF RELATED CASES

This case is a continuation-in-part with U.S. patent application Ser. No. 15/632,462 filed Jun. 26, 2017. This case claims priority from U.S. Provisional Patent No. 62/707,208 filed Oct. 25, 2017. The above listed cases are incorporated herein by reference. If there are any contradictions or inconsistencies in language between this application and the cases that have been incorporated by reference that might affect the interpretation of the claims in this case, these related claims should be interpreted to be consistent with the language in this case.

### FIELD OF THE INVENTION

The present invention pertains to a semiconductor sensor device, and in particular to a convective accelerometer.

### BACKGROUND OF THE INVENTION

Accelerometers have emerged as a ubiquitous sensor having high demand in the fields of consumer electronics, automotive, biomedical, defense, aerospace, navigation and industrial applications. Rapid progress of semiconductor fabrication technology has led to the development of predominantly silicon-based micro-electromechanical (MEMS) accelerometers.

Thermal micro-sensors have been developed for many applications during the past 25 years. Some of the earliest thermal sensors comprised of micro-platforms were physically configured as infrared detectors fabricated using semiconductor wafers. T

Thermal micro-platforms have been physically configured for inertial, gravimetric, flow, pressure, photonic, chemical, nuclear and electrical.

Thermal accelerometers have been developed based on both MEMS and micro-thermal technologies. Prior art convective accelerometers comprised of a suspended heater and thermistor are disclosed in prior art U.S. Pat. Nos. 5,581,034 and 6,589,433. Prior art discloses convective accelerometers comprised of a thermal heater and a thermal sensor as separate structures disposed within a convective fluid sensitive to inertial forces including physical movement and gravity.

Convective accelerometers have no solid proof mass which changes its position or shape due to an applied acceleration. Convective accelerometers sense the displacement of a tiny heated fluid bubble present within a sealed cavity. As there is no solid seismic mass, the shock survivability and opportunity for useful of very high acceleration magnitudes is more readily obtained with a convective accelerometer. The integration of the a convective accelerometer with complementary metal-oxide semiconductor (CMOS) signal conditioning integrated circuitry on the same silicon die is also convenient.

There is a need for convective accelerometers providing increased dynamic range, accuracy, inertial sensitivity, power efficiency, manufacturing process compatibility, robustness, and reduced cost and smaller footprint. There is also the need for a convective accelerometer of increased dynamic range physically configured to provide a 6-axis inertial measurement unit (IMU).

### SUMMARY OF THE INVENTION

The present invention provides a convective inertial accelerometer which in embodiments provides one or more of a linear accelerometer, angular (rate sensor) accelerometer and inclinometer function. In embodiments, the accelerometer is configured to provide a multi-axis accelerometer. One some embodiments, the accelerometer is configured to provide a 6-axis inertial measurement unit (IMU).

The salient features of the convective inertial accelerometer include: A convective accelerometer formed by creating thermal heaters and thermal temperature sensors at fixed positions within a cavity which is filled with a fluid. The convective accelerometer is comprised of one or more heater thermal elements and sensor thermal elements disposed within a cavity. The cavity is filled with a fluid providing a convective thermal transport from the heater thermal elements to sensor thermal elements, wherein:
each thermal element is comprised of one or more micro-platforms wherein each micro-platform is supported by a plurality of nanowires;
each nanowire is partially disposed on the one or more micro-platforms and an off-platform region, the off-platform region at least partially surrounding the micro-platform;
one or more of the plurality of nanowires is physically configured with one or more first layers, the one or more nanowire first layers comprised of phononic scattering nanostructures and/or phononic resonant nanostructures;
the one or more first layers of the plurality nanowires provides a reduction in the ratio of thermal conductivity to electrical conductivity, and
the thermal elements provide a means for creating and sensing a vectored change in thermal transport by free convection through the fluid within the cavity.

The dimensions of the cavity and placement of thermal elements therein permits monitoring the convective flow of fluid within the cavity under the influence of acceleration. In this invention, the thermal transport rate from heater to sensor is a function of acceleration forces resulting from vibration, shock and gravity. Convective thermal transport as monitored by a thermal sensor, therein provides an accelerometer function. The thermal heater element and a thermal sensor element are separated from one another by a distance wherein convective thermal conductivity through the fluid is greater than molecular thermal conductivity. For a gas fluid, the minimum separation distance must be much greater than the mean free path for collisions between individual gas molecules within the cavity. In embodiments of the present invention, this separation is generally greater than 50 micrometers.

The thermal response of the convective accelerometer to acceleration is linear over a wide range. However, at sufficiently large acceleration levels, the thermal response saturates. In embodiments, the accelerometer is operated to provide a linear response over a wide range of acceleration vector magnitudes. In other embodiments, wherein the accelerometer response saturates, the accelerometer provides a means of determining if the sensed acceleration has crossed a threshold value.

In embodiments, the accelerometer is configured with multiple convective paths to monitor accelerations in selected vectored directions, thereby providing a multi-axis accelerometer. The accelerometer may be structured to provide a more sensitive response for some vectored directions. In applications wherein only a threshold level for saturation is of interest, the required signal conditioning circuitry is simplified.

Relating to the micro-platform and thermal time constants: The thermal heater element and a temperature sensing element are generally disposed on separate micro-platforms thermally-coupled through fluid within the cavity. In embodiments, the micro-platform thermal elements and a cavity are formed from a semiconductor-on-insulator (SOI) starting wafer. The SOI wafer, in exemplary embodiments, is a silicon SOI starting wafer processed at wafer scale. Wafer dicing to provide micro-platforms is performed as a post-cleanroom step prior to die bonding and die packaging. Individual die may be comprised of both convective accelerometers and integrated circuits including CMOS circuits.

The micro-platform is physically configured with submicron thickness and appropriate area. The ratio of thermal heat capacity of the micro-platform to the thermal conductivity of the supporting nanowires determines a first thermal time constant for the accelerometer. This first thermal time constant, in embodiments, varies from microseconds to seconds. The propagation of heat through the cavity fluid through the thermal transport path determines a second thermal time constant for the accelerometer. The overall thermal time constant for accelerometer response is determined by cascade of the first and second component time constants. In this invention, this overall time constant is determined by the fluid species and density, heater and sensor dimensions, heater and sensor locations within the cavity, platform and nanowire materials together with nanowire phononic structures. The overall thermal time constant in embodiments varies from less than 1 millisecond to over 1 second.

Relating now to the nanowires: The micro-platform is supported by semiconductor nanowires comprised of phononic structures which scatter and/or provide a local resonance for heat conducting phonons thereby reducing thermal conductivity along the length of the nanowire. In embodiments, nanowires are comprised of the device layer of a starting SOI wafer. The phononic structures are configured to not limit the scattering range for electrons.

In embodiments of this invention, a nanowire first film is comprised of a semiconductor where the difference in mean free path for phonons and electrons is significant. Typically, in embodiment nanowires, the mean free path for electron ranges from less than 1 nm up to 10 nm. The mean free path for phonons that dominate the thermal transport within nanowires of the present invention is within the range 20 to 2000 nm, significantly larger than for electrons. In embodiments comprising silicon nanowires, the structures restricting phonon thermal transport have dimensions of less than the phonon mean free path and greater than the electron mean free path. The semiconductor nanowires used to support micro-platforms in this invention are lithographically formed from a phononically-structured first semiconductor film. These structures reduce the thermal conductivity of the nanowire without appreciably reducing the electrical conductivity.

In some embodiments, nanowires are comprised of phononic scattering and/or resonant structures created by patterning the first layer of a nanowire with physical holes of nanometer dimension using submicron lithography. This particular type of texturing creates a patterned “holey” or cavitated structure into the first layer of nanowires and provides a desirable reduction in thermal conductivity along the length of the wire.

In some other embodiments, the semiconductor first layer film of a nanowire is created using a solgel, electrochemical or multi-source evaporation/sputtering process to deposit a film which is appropriately lithographically patterned. Upon subsequent thermal annealing, porous and/or particulate structures form providing a desirable phononic scattering. In these embodiments, phononic scattering structures of desirable dimensions are created “in situ” within the nanowire, somewhat randomly disposed, to provide a reduction in the mean free path of thermally conducting phonons. Synthesis of thin films of submicron thickness with porous or particulate-structure is well known to those familiar with the art.

In embodiments, the semiconductor first layer of a nanowire is a semiconductor selected from a group including, without limitation, Si, Ge, SiGe, ZnO₂, GaAs, Ga₂O₃, GaN, Bi₂Te₃, CoSb₃, AsH₃, Sb₂Te₃, La₃Te₄, SiC, GaN, (Bi₁₋ₓSbₓ)₂Te₃ and binary/ternary alloys thereof.

In embodiments, some nanowires are comprised of multiple, stacked films in addition to the semiconductor first film. These additional films are dielectrics and/or nano-thickness ALD metal films with limited thermal conduction. In some embodiments a metal ALD of nano-thickness provides a desirable additional electrical conductance in addition to the electrical conductance of the first nanowire layer for signals or power through the nanowire. The metal ALD film of nanometer thickness in nanowire embodiments is selected from a group including, without limitation, Pt, W. Pd, Cu, Mo and Al. In embodiments, the metal ALD film extends beyond the nanowire onto a micro-platform providing an ohmic connection to a thermal heating element.

In embodiments, a dielectric film of low thermal conductivity is disposed between a metal ALD film and the semiconductor first film of the nanowire providing two separate, isolated electrical connections between on- and off-platform circuits. In other embodiments, the semiconductor first nanowire is created with a covering dielectric film which provides a desirable longitudinal mechanical stress to change the elevation of the suspended micro-platform and/or reduce stress across the micro-platform. The dielectric layer, in embodiments, is disposed beyond the nanowire and onto the micro-platform providing a biaxial compressive or tensile stress as appropriate to reduce overall stress across the micro-platform. In embodiments, the thin film dielectric material is selected from one or more of, without limitation, silicon nitride, silicon oxynitride, aluminum oxide, silicon dioxide, PDMS and SU-8.

Relating now to the heater thermal elements: In embodiments, the temperature of the micro-platform may be controlled by powering a resistive heater with closed loop control over a wide range of temperature. The heater may be comprised of a resistive metal film or a semiconductor film. In embodiments, the heater of metal film is typically comprised of one or more of the same semiconductor as the nanowire, but may also be an ALD metal such as W, NiCr, Pd, Ti, Cu, Pt, and Al of nanometer thickness with an underlying ALD adhesion enhancer such as Ti or Cr. For embodiments with a silicon micro-platform, the maximum long term heater temperature is 500° C. By comparison, an accelerometer with a SiC microplatform and SiC nanowires can operate at temperatures of over 1000° C. In some embodiments, the heater thermal element is a thermistor or thermoelectric element externally driven to a power level providing an adequate source of heat for thermal excitation.

Relating now to the sensor thermal elements: The thermal sensor element is positioned to sense temperature of the fluid after it is heated by convective thermal transport from the heater element and modulated by acceleration. In embodiments, the thermal sensing element is a thermistor comprising a metal ALD film or a semiconductor. A thermister thermal sensing element may be comprised of an extended portion of a nanowire.

In other embodiments, the thermal sensor element is comprised of a thermoelectric device operated in the Seebeck mode providing a precision measurement of temperature of the contacting fluid. The Seebeck sensor generates a voltage proportional to the temperature difference between the on-platform junction and the off-platform junctions. A plurality of Seebeck sensors are generally series-connected to provide an optimized overall sensor signal-to-noise ratio. In embodiments, the Seebeck thermal element provides a determination of convective temperature differential ranging from less than 1 microdegree Centigrade to over 1 degree Centigrade in response to acceleration vectors.

In embodiments, in addition to the thermal elements disposed within the cavity on a micro-platform, a reference sensor for temperature is disposed in the off-platform surrounding support area. The reference sensor is used for calibration purposes. The reference sensor may be comprised of one or more of a metal film thermistor, a semiconductor thermister, bandgap diode, MOS transistor and bipolar transistor operated in a VPTAT/IPTAT mode.

In embodiments, signal conditioning circuitry, typically in the form of CMOS-compatible structures, may include a Wheatstone bridge, amplification, synchronous double-sampled filtering, conventional filtering, analog to digital converter and threshold level trigger.

Relating now to processing, packaging and assembly: In embodiments, electrical connection with circuits external to the accelerometer may be comprised of bonding pads or bonding bumps. Electrical interconnects with supporting nanowires may be formed as a metal film, semiconductor and through-semiconductor-via (TSV).

In embodiments, thermal elements are disposed on two separate wafers processed to provide a 2-level accelerometer. The two wafers are bonded by appropriate wafer bonding using materials such as epoxy, metallization and in some cases a direct semiconductor-to-semiconductor thermal bonding prior to additional post-cleanroom wafer processing. In other embodiments, the convective accelerometer is structured from more than two starting wafers.

In the exemplary embodiments of this invention, the starting wafer is a silicon SOI wafer. The SOI wafer in these exemplary embodiments is comprised of a silicon first semiconductor device layer of appropriate electrical conductivity, a buried silicon dioxide dielectric (BOX) film, and an underlying silicon handle substrate. The SOI starting wafer is typically manufactured by processes such as SMARTCUT™, SIMOX, and BESOI. The SOI wafer is processed using cleanroom tools including submicron optical and e-beam lithography, CVD, PVD, co-evaporation, multi-target magnetron and RF sputtering, RTP, RIE, DRIE, annealing/diffusion furnaces and metrology familiar to those of ordinary skill in the art. In embodiments, processing of the silicon device layer may include fabrication of integrated circuits, especially CMOS circuits disposed on or off the micro-platform. Final processing steps prior to assembly include release of the micro-platform using a backside or frontside etch followed by wafer dicing. Wafer handler cassettes designed to protect wafers with fragile micro-platform structures are used as necessary for wafers with released micro-platforms.

To package the accelerometer after it is processed at wafer scale, dicing techniques are used which do not damage the micro-platform and nanowire. For example, dicing is performed using a CO₂ laser scribe operated to minimize ablation.

Silicon die are assembled on headers or other substrates by precision pick and place robotic tools or using a manual placement micromanipulator. Die bonding is implemented with assembly processes that avoid damage to the micro-platform and support structure. Ultrasonic wire bonding, metal pads or solder bumps are used for connections within headers or onto circuit boards.

It is an object of the present invention to provide an accelerometer sensitive to one or more vectored accelerations. In some embodiments, the accelerometer is physically configured to provide a 6-axis inertial measurement unit (IMU).

More specifically, it is an object of the present invention to provide a convective inertial accelerometer for monitoring linear acceleration, angular acceleration and inclination. It is an object of the present invention to provide an accelerometer physically configured with phononic nanowires. It is another object of the present invention to provide an accelerometer where a single thermal element is operated as both a thermal heater and a temperature sensor comprised of a resistive device and/or a thermoelectric device. It is an object of the present invention to provide an integrated accelerometer with integrated signal conditioning circuitry on the same semiconductor substrate. It is an object of the present invention to provide an accelerometer comprised of a mobile phone or a node within a wireless communication network. It is an object of the present invention to provide an accelerometer for mounting on machinery and wearable sports equipment for the purpose of monitoring vibration and shock. It is an object of the present invention to provide a cost effective convective accelerometer having increased dynamic range, accuracy, inertial sensitivity, power efficiency, manufacturing process compatibility, robustness, and reduced physical footprint

### BRIEF DESCRIPTION OF THE FIGURES

FIG. 1 Depicts a plan view of a prior art thermocouple having phononic nanowire structure.

FIG. 2A Plan view depicting a single axis linear thermal accelerometer with phononic nanowire structure in accordance with the present teachings.

FIG. 2B Depicts a cross-sectional view depicting the accelerometer of FIG. 2A

FIG. 3 depicts a plan view depicting a Coriolis angular rate accelerometer with phononic nanowire structure in accordance with the present teachings.

FIG. 4A is a schematic illustration of a multi-axis convective accelerometer in accordance with the present teachings.

FIG. 4B depicts a plan view depicting the multi-axis convective accelerometer of FIG. 4A configured in a circular format.

FIG. 5A depicts plan view of a multi-axis convective accelerometer configured in a rectangular format in accordance with the present teachings.

FIG. 5B depicts a cross-sectional view of the accelerometer of FIG. 5A formed from two bonded wafers.

### DETAIL DESCRIPTION

Definitions: The following terms as explicitly defined for use in this disclosure and the appended claims:

“disposed on” or “disposed in” means attached to and/or created within.

“providing” means physically configured and/or operated to provide.

“inertial accelerometer” means an accelerometer providing a vectored measurement of either linear acceleration and/or angular rate acceleration.

“inertial measurement unit” or “IMU is a sensor providing a measurement of both a linear acceleration vector and an angular acceleration vector.

“convective accelerometer” means an accelerometer wherein vectored accelerations are determined by sensing the convective flow of a convective fluid disposed within a cavity and affected by acceleration.

“convective cavity” or “cavity” in this invention means the hermetic volume containing the thermal elements.

“fluid media”, “convective fluid” or “fluid” means the gas or liquid within the cavity in thermal contact with the thermal elements.

“thermal micro-platform” means a platform supported by nanowires wherein the nanowires provide a conducted thermal isolation with respect to a surrounding support platform.

“thermal element” means the heater or the temperature sensor disposed within the cavity and comprised of a micro-platform and supporting metamaterial nanowires.

“heater thermal element” means any externally-powered device heating a micro-platform including a resistive heater.

“sensor thermal element” refers to a thermal element operated to monitor temperature such as a thermistor or Seebeck thermoelectric device.

“reference sensor” refers to a temperature sensor disposed outside the cavity and providing a calibration reference.

“metamaterial nanowire” or “phononic-structured nanowire” means a semiconductor of nano-dimensioned structure physically configured for scattering or resonating phonons thereby providing a reduction in thermal conductivity. The metamaterial nanowire may comprise surface, bulk, and embedded structures for Umklapp and other scattering, Bragg resonance and Mie resonance of phonons

“convective conditioning structure” means a physical structure interposed into the convective path within the cavity, deflecting the convective thermal transport in a manner which improves one or more accelerometer performance parameters.

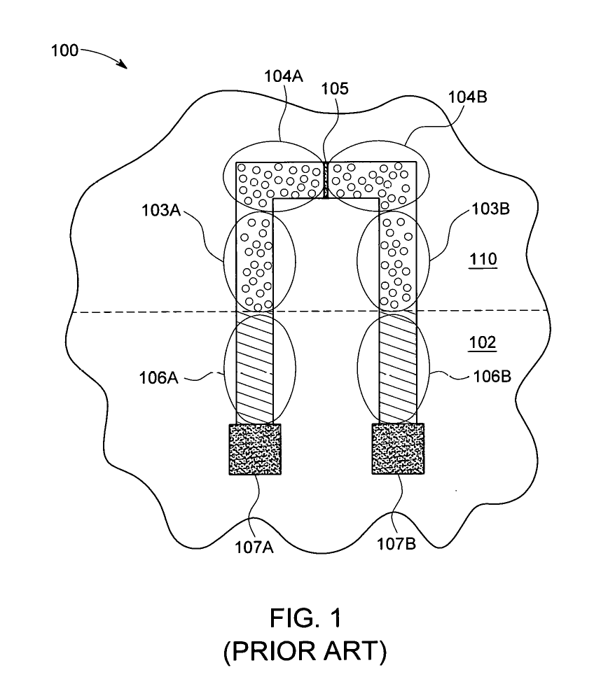

FIG. 1 depicts the plan view of a sensor thermal element within the accelerometer. In this illustrative embodiment, a single thermoelectric couple is comprised of a p-type semiconductor and n-type semiconductor arm partially disposed on a surrounding support platform 102. The p-type semiconductor comprises micro-platform area 104A, nanowire 103A, interconnection 106A, and electrical contact bonding pad 107A. The n-type semiconductor comprises micro-platform area 104B, nanowire 103B, interconnection 106B, and electrical contact bonding pad 107B. The interconnections 106A and 106B are disposed on the surrounding support platform 102. The nanowires and micro-platform extend into the cavity volume 110. The micro-platform 104A and 104B is incrementally heated with convective thermal transport from the heater thermal element.

In all embodiments, the thermal conductivity of the nanowires 103A and 103B is advantageously reduced by the physical structuring. In an exemplary embodiment, separation between phononic scattering or resonant structures. In other embodiments, the phononic structure supports a phononic resonance. In all embodiments, the metamaterial nanowire structure lowers the ratio of thermal conductivity to electrical conductivity.

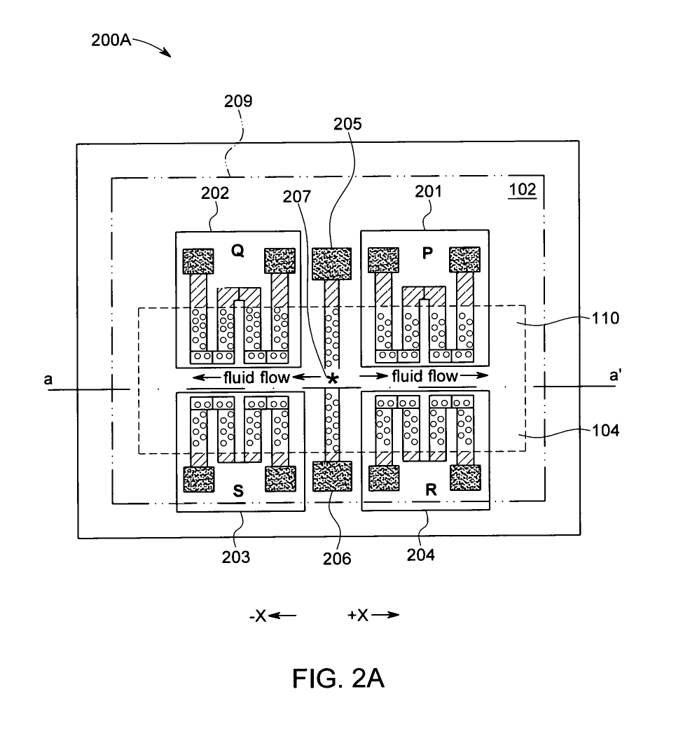

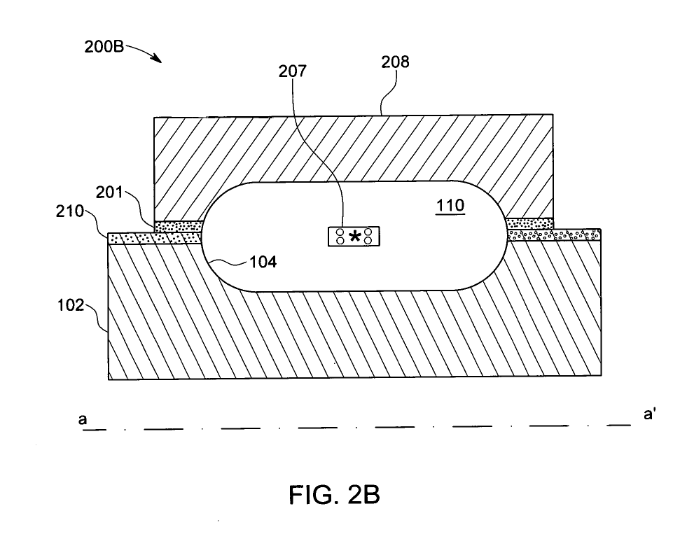

FIG. 2A depicts an plan view of a single axis linear accelerometer embodiment. The heater thermal element 207 is powered externally through contacts 205 and 206 and heats a bubble within fluid in the immediate vicinity within the cavity 110 bounded by perimeter 104. If the accelerometer is accelerated in a positive x-direction, then the Seebeck thermal elements Q 202 and S 203 are incrementally heated more than thermal elements P 201 204 and R due to convective motion of the heated bubble. If the accelerometer is accelerated in the negative x-direction, then thermal elements P and R are heated more than thermal elements Q and S. Acceleration in the x-axis directions is sensed as voltage from Seebeck thermal elements P, Q, R and S. When the accelerometer is calibrated using a rate table, the magnitude of x-axis acceleration is quantified. The thermal elements are disposed on a first wafer having cavity 110. The remainder of the cavity 110 is formed within a second cap wafer.

FIG. 2B depicts a cross-sectional view of the accelerometer of FIG. 2A as defined by section a-a′. The cavity 110 is bounded by the first wafer configured with a surrounding substrate 102, and an oxide film 210. The cavity 110 is bounded above by substrate 208. A eutectic film 210 is used to bond the two wafers and hermetically seal the cavity. The cross-section a-a′ includes the heater thermal element 207.

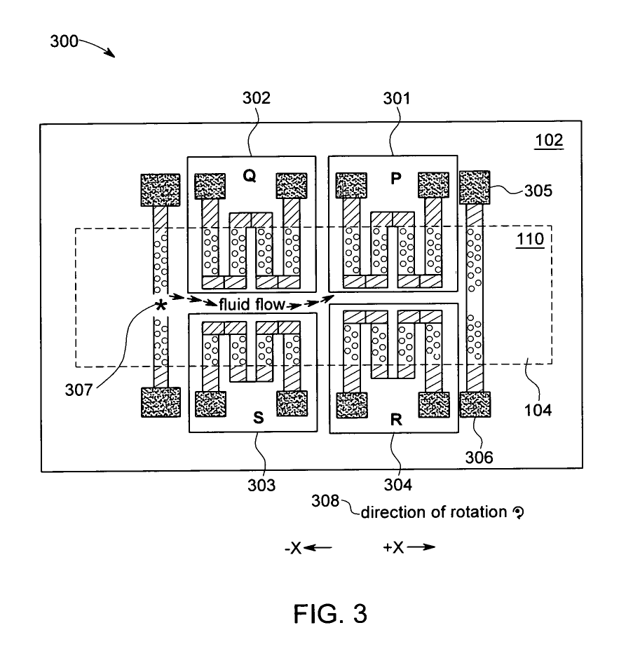

FIG. 3 depicts a plan view of a Coriolis or angular rate accelerometer embodiment with one heater thermal element indicated by heated area 307 and another heater thermal element with bonding pads 305 and 306. The thermal elements are disposed in cavity 110 bounded by periphery 104 within surrounding support structure 102. The heated area 307, when affected by acceleration in the negative x-axis direction, heats Seebeck thermal elements Q 302 and S 303 along the convective path to sensors P 301 and R 304. With angular rotation − [symbol] _{z}, 308 about the z-axis, thermal elements Q 302 and P 301 are incrementally heated more than thermal elements S 303 and R 304 due to angular acceleration. Angular rotation + [symbol] _{z}, in the opposite direction − [symbol] _{z}, is sensed as voltage from Seebeck thermal elements P, Q, R and S when the thermal bubble is created by the heater connected with bonding pads 305 and 306. When the accelerometer is calibrated using a rate table, the magnitude of x-axis acceleration is quantified.

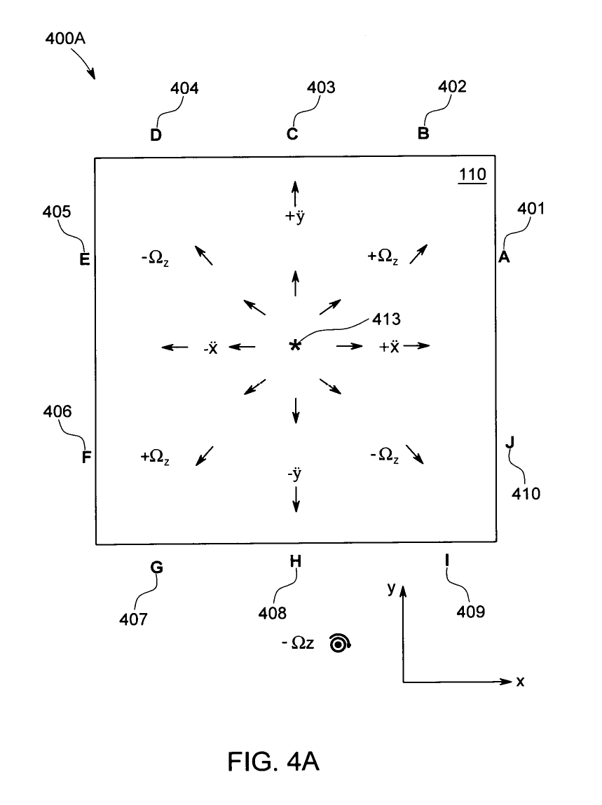

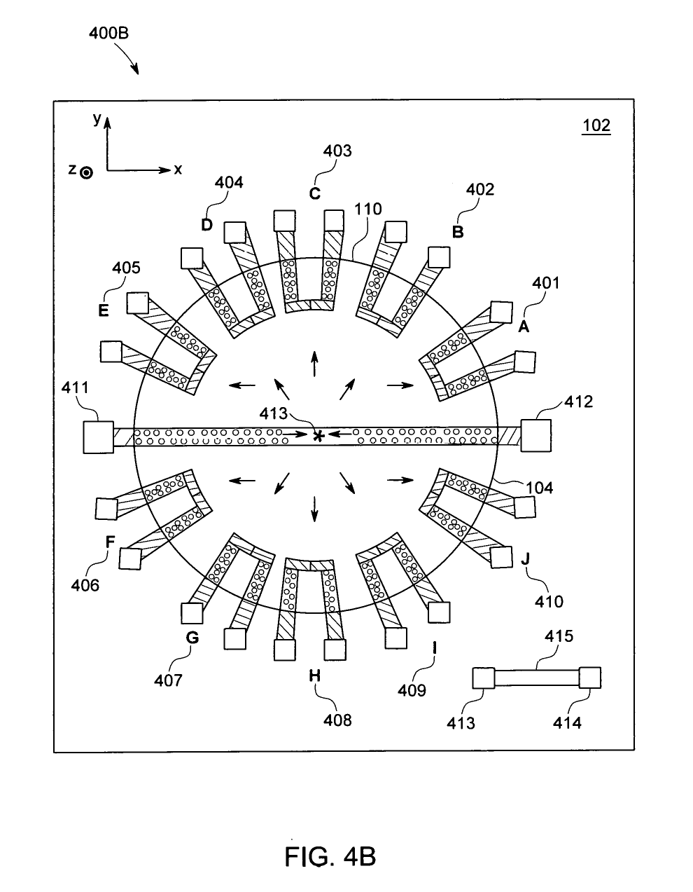

FIG. 4A is a schematic depiction of two-dimensional thermal transport sensed by ten Seebeck thermal sensors (A-J) disposed at the periphery of a cavity heated from a central hot spot 413. In this embodiment, the convective spectrometer provides a two-axis linear accelerometer for x- and y-axis accelerations and a single axis angular accelerometer (+ [symbol] _{z}, and − [symbol] _{z}).

In FIG. 4A a linear acceleration in the +x vector direction, heats sensors at positions E 405 and F 406 more than sensors at positions A 401 and J 402. An acceleration in the −x direction incrementally heats sensors at positions A 401 and J 410 more than sensors at positions E 405 and F 406. Similarly, an acceleration in the +y direction incrementally heats sensors at positions G, H and I more than sensors at positions B, C and D. An acceleration in the −y direction heats sensors at positions B, C and D more than sensors at positions G, H and I. When the accelerometer is rotated + [symbol] _{z} about the +z axis, the acceleration incrementally heats sensors at positions D, E and I, J more than sensors A, B and F, G. When the accelerometer is rotated in the opposite direction − [symbol] _{z} about the z-axis, then sensors located at A, B and F, G are heated more than sensors located at D, E and I, J.

FIG. 4B depicts the structure and thermal elements depicted in FIG. 4A more clearly where the heater thermal element 413 is surrounded by sensor thermal elements A-J. Thermal heater element 413 suspended with nanowires over cavity 110 with periphery 104 is contained within surrounding support platform 102. Peltier thermoelectric sensor thermal elements A-J are disposed around the cavity 110 periphery with micro-platforms and nanowires extending into the cavity 110. In embodiments, where less sensitivity is required, the sensor thermal elements may be comprised of thermistors. Where a maximum sensitivity for temperature is required, the Peltier thermoelectric thermal elements are comprised of an array having many thermocouples connected in series. The series connection when optimized provides an increased in signal level and an overall increase in signal to noise ratio for the Peltier array. In most embodiments, the temperature of the surrounding support platform is needed for calibration purposes. This reference sensor is depicted as a thermistor 415 contacted with bonding pads 413 and 414.

The accelerometer structure of FIGS. 4A and 4B as presented above provides an inertial measurement unit having sensitivity for two linear axes (x and y) and sensitivity for one rotational axis [symbol] _{z}.

The accelerometer of FIGS. 4A and 4B also may provide an inertial measurement unit (IMU) with sensitivity to linear acceleration to movements in all three cartesian axes in additional to sensitivity to rotational acceleration around these same three axes. Reduced sensitivity is obtained for linear acceleration in the +/−z-directions by sensing the average signal level of all 10 sensors without any differential reference. For instance, a uniform overall reduction in all sensor levels is affected by a linear z-axis acceleration. Sensitivity is obtained for rotational acceleration [symbol] _{z} around the x-axis wherein the signal levels at sensors B, C and D are differentially affected. Similarly, sensitivity for rotational acceleration [symbol] _{y} around the y-axis is provided by the differential signal levels of sensors E and F compared with A and J.

To obtain a measure of all vectored acceleration amplitudes, a multivariate analysis of signals from the 10 sensor thermal elements is processed by an acceleration analyzer. The accelerometer signals are determined for a range of accelerations using a rate table to obtain a reference calibration database. The accelerometer is placed in service and subjected to application specific accelerations to obtain an application database. An acceleration analyzer processes the reference database and the application database to quantify the vectored amplitudes of the application specific acceleration using multivariate analyses based on one or more of the 10 variables.

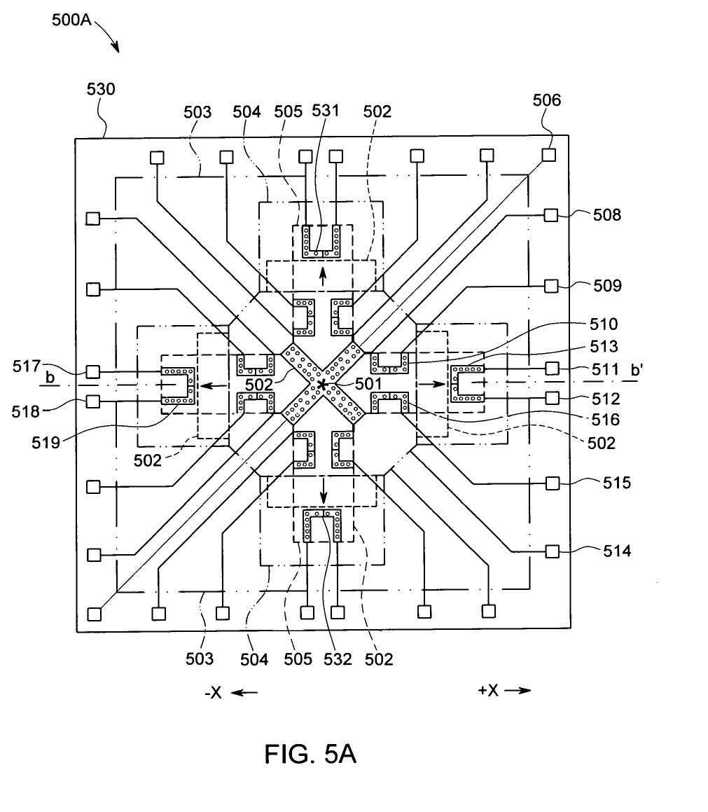

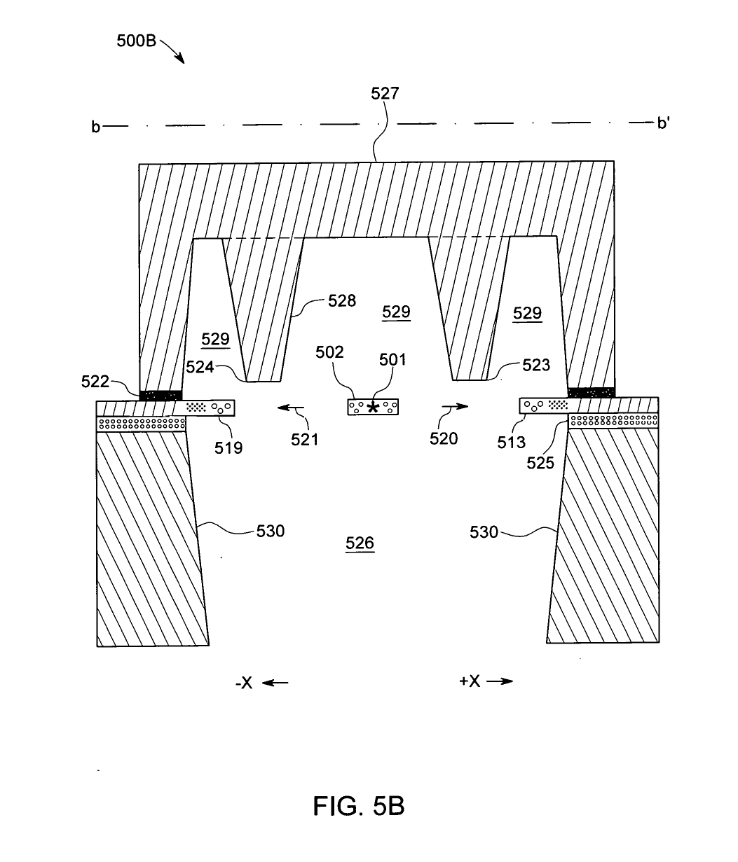

FIGS. 5A and 5B depict the respective plan and cross-section b-b′ views of the convective accelerometer structurally configured for enhanced inertial response. This embodiment is comprised of 12 Seebeck thermal elements disposed around the periphery 505 of cavities 526, 529 and 529. Heater thermal element 501 with micro-platform/nanowire structure 502 is suspended within the cavity. All thermal elements are partially supported by the surrounding support platform 530 and dielectric insulator film 525.

In FIG. 5A the convective transport path terminating into the four remote Peltier sensor thermal elements 513, 519, 530 and 531 is modified by flow conditioning structures 502 in FIG. 5A. In FIG. 5B these convective flow conditioning structures are depicted as 528 with surfaces 523 and 524. These structures 502 reduce the cross-sectional area for thermal transport in the convective paths depicted as 520 and 521. These structures partially block thermal transport to the sensor thermal elements 511, 519, 531 and 532 and reduce the sensed signal level. In this embodiment, structures 502 increase the threshold level at which convective thermal saturation occurs thereby increasing the upper range for acceleration sensing. In other embodiments, the cavity may be shaped to provide a channel of decreasing cross-section to concentrate convective flow into a sensor thermal element thereby increasing sensitivity to an acceleration vector.

Sensing of accelerations in a lower range is provided by 8 of the 10 sensor thermal elements (including elements 510, 515) disposed symmetrically around the periphery of cavity 526, 529. The total of 10 sensor elements permit sensing of up to 6 acceleration axes including an extended range for linear accelerations for vectored axes x and y. This accelerometer is operated in a similar manner to that disclosed for the accelerometer of FIG. 4.

The accelerometer in cross-sectional view of FIG. 5B is comprised of two structural support wafers 527 and 530 bonded together with eutectic metal, adhesive such as epoxy, or in some embodiments, direct wafer to wafer bonding. In the exemplary embodiment, the lower wafer is formed of a starting silicon SOI wafer and the upper capping wafer is formed of a starting silicon wafer.

In embodiments, the accelerometer is formed of semiconductor, ceramic, and glass wafers. In embodiments, the accelerometer if formed of surrounding support structures formed by 3-D additive printing technology.

In some other embodiments, nanowires 101 are physically created in situ by thin film deposition and annealing processes. These synthesis processes use appropriate precursors and specialized thermal annealing to form nanowires with mesoporous or clustered semiconductor phononic scattering structures comprised of one or more semiconductor material

In embodiments, the metal layer increases the electrical conductivity of the nanowire and is created by sputtering or evaporative deposition to provide a film, generally an ALD film. FIG. 3B depicts a nanowire 101 physically configured with a dielectric layer 106 sandwiched between an overlying metal film 105 and the device layer 300 of the starting wafer. The dielectric layer in some embodiments includes Si₃N₄ obtained by a CVD process using NH₃ and SiH₄ as precursors. In other embodiments, the dielectric layer 106 is SiO₂ obtained by using a oxide target with RF sputtering. In other embodiments, the dielectric layer 106 is a film of Al₂O₃ obtained using a CVD deposition or reactive sputtering process

The Seebeck thermoelectric sensors are formed into the silicon device layer by creating alternate heavily doped p- and n-type regions using typically SOG-based dopant with boron and phosphorus.

Next, level1 vias 1310, 1320 and 1330 and level2 vias 1340 and 1350 are created. The vias are typically formed using a combination of DRIE etching and electroless- or electro-plating of a conductor such as Cu over a thin adhesion layer. Cavities 108 are etched from the backside with cavity areas defined by patterned film such as silicon dioxide or a metal such as Cd. Next, wafers are bonded together using an epoxy, metal, direct bonding process. In this embodiment, solder bumps 1360 are created by electroplating the bonded wafers to provide a flip-chip accelerometer 1300 for soldering directly to a printed circuit board. In other embodiments, contact pads much smaller than solder bumps are used in order to reduce the accelerometer footprint.

Although various embodiments of this invention have been described above with a certain degree of particularity, or with reference to one or more individual embodiments, those skilled in the art could make numerous alterations to the disclosed embodiments without departing from the spirit or scope of this invention. It is intended that all matter contained in the above description and shown in the accompanying drawings shall be interpreted as illustrative only of particular embodiments and not limiting. Changes in detail or structure may be made without departing from the basic elements of the invention as defined in the following claims.

What is claimed is:

1. A convective accelerometer comprised of one or more heater thermal elements and one or more sensor thermal elements disposed within a cavity, the cavity filled with a fluid providing a convective thermal transport from the heater thermal elements to sensor thermal elements, wherein:
each thermal element is comprised of one or more micro-platforms wherein each micro-platform is supported by a plurality of nanowires;
each nanowire is partially disposed on the one or more micro-platforms and an off-platform region, the off-platform region at least partially surrounding the micro-platform;
one or more of the plurality of nanowires is physically configured with one or more first layers, the one or more nanowire first layers comprised of phononic scattering nanostructures and/or phononic resonant nanostructures;
the one or more first layers of the plurality nanowires provides a reduction in the ratio of thermal conductivity to electrical conductivity, and
the thermal elements provide a means for creating and sensing a vectored change in thermal transport by free convection through the fluid within the cavity.

2. The accelerometer of claim 1 structurally configured with one or more heater thermal elements comprised of resistive heaters.

3. The accelerometer of claim 1 structurally configured with one or more sensor thermal elements comprised of thermistor devices and/or Seebeck thermoelectric devices.

4. The accelerometer of claim 1 comprised of one or more convective conditioning structures restricting and/or guiding the convective thermal transport, the structures providing improvement in an accelerometer performance parameter.

5. The accelerometer of claim 1 wherein the thermal elements are positioned within the cavity to minimize molecular thermal conduction through the fluid and maximize the convective thermal conduction to sensor thermal elements.

6. The accelerometer of claim 1 wherein the fluid within the cavity is comprised of at least one of N₂, He, Ar, Xe, Ne, Kr, SF₆ and CO₂.

7. The accelerometer of claim 1 structurally configured with a reference device comprised of a thermistor or bandgap diode disposed in the off-platform region providing a measurement of absolute temperature.

8. The accelerometer of claim 1 physically configured to provide one or more of linear acceleration, angular acceleration, and inclination vectors.

9. The accelerometer of claim 1 wherein the one or more first layers of the plurality of nanowires is comprised of one or more of semiconductors silicon, germanium, SiGe alloy, SiC, GaN, bismuth and lead chalcoginides, AsH₃, CoSb₃, metal oxides and binary/ternary alloys thereof.

10. The accelerometer of claim 1 wherein the one or more of the plurality of nanowires is comprised of a second layer, the second layer further comprised of an ALD metal selected from one or more of W, Pd, Pt, Mo, Ni, Al, Ag and Au providing an increased electrical conductivity for said nanowire.

11. The accelerometer of claim 1 wherein the one or more of the plurality of nanowires is comprised of a third layer, the third layer further comprised of a dielectric film providing a means for mechanical stress control and/or electrical isolation.

12. The accelerometer of claim 1 wherein the sensor thermal elements are physically configured to provide a differential signal voltage or a unbalanced signal voltage.

13. The accelerometer of claim 1 wherein a heater element is supplied with a constant power to provide a reference quiescent signal level.

14. The accelerometer of claim 1 wherein the sensing thermal elements have an incremental temperature detection limit ranging from less than 1 microdegree Centigrade to 1 degree Centigrade.

15. The accelerometer of claim 1 wherein the cavity has enclosing structural dimensions ranging upward from 100 micrometers.

16. The accelerometer of claim 1 with internal and external electrical connection structure comprising one or more of wire bonding pads, metal interconnect pads and through-semiconductor vias (TSV).

17. The accelerometer of claim 1 wherein the thermal elements are disposed in a single plane or a plurality of planes.

18. The accelerometer of claim 1 structured from a plurality of bonded wafers including at least one semiconductor-on-insulator (SOI) starting wafer

19. The accelerometer of claim 1 disposed within or near a mobile phone, within a wireless network or within a mounted module.

20. A method for sensing acceleration based on the convective accelerometer of claim 1 and the use of an acceleration analyzer, wherein the method is comprised of a sequence of steps:
position the convective accelerometer on a calibrated rate table programmed with known vectored accelerations to obtain a calibration database1 of vectored accelerations;
operate the convective accelerometer in an application acceleration environment to obtain a calibration database2 of sensor signal levels.
develop a multivariate algorithm to uniquely specify a vectored magnitude accelerations for application accelerometer signals based on calibration database1 and calibration database2;
operate the accelerometer in an application environment and obtain database3 comprised of application accelerometer signals.
determine the vectored magnitude accelerations corresponding to signal levels contained within database3 using the acceleration analyzer programmed with the multivariate algorithm.
